(19) United States
(12) Patent Application Publication
(10) Pub. No.: US 2018/0183380 A1
(43) Pub. Date: Jun. 28, 2018

(54) Fluid-Cooled Blind Panels Configured to Generate Electricity and Heat

(71) Applicant: Gary R. Gustafson, Minneapolis, MN (US)

(72) Inventor: Gary R. Gustafson, Minneapolis, MN (US)

(21) Appl. No.: 15/736,460

(22) PCT Filed: Jun. 9, 2016
(86) PCT No.: PCT/US16/36630

§ 371 Date: Dec. 14, 2017

Related U.S. Application Data
(60) Provisional application No. 62/181,798, filed on Jun. 19, 2015.

(51) Int. Cl. H02S 10/30; H01L 35/32; H01L 35/02; H02S 40/42; H02S 20/30

(52) U.S. Cl. CPC H02S 10/30; F24J 2/242; F24J 2/4647; F24J 2/0023; H02S 20/30; F24J 2/541; H01L 35/32; H01L 35/02; H02S 40/425; F24J 2/50

(57) ABSTRACT

The present invention is an apparatus and method using solar insolation to heat fluid moving through panels, resulting in relatively hot fluid. A set of such panels might be installed in a window. Heat is removed from the hot fluid in a heat reservoir or heat sink, resulting in relatively cool fluid. In some embodiments, the hot fluid and the cool fluid are placed in thermal contact with opposite sides of a thermoelectric generator, thereby generating electricity. In some embodiments, photovoltaic cell modules are embedded in the panels, the fluid system improving the effectiveness of the cells. A given system might use either approach to generate electricity, or both. Heat from the heat reservoir might be used to heat a building. A thermoelectric system might be run in reverse at night.

### CROSS-REFERENCES TO RELATED APPLICATIONS

This application claims the benefit of provisional U.S. Application No. 62/181,798, filed Jun. 19, 2015, and hereby incorporated by reference in its entirety.

### FIELD OF THE INVENTION

The present invention relates to generation of electricity and heat from incoming solar radiation (insolation). More specifically, the present invention relates to fluid cooled panels that utilize thermoelectric generation and/or photovoltaic cells.

### BACKGROUND OF THE INVENTION

FIG. 1a is a schematic diagram of a thermoelectric generator 100. A thermoelectric generator 100 extracts electrical energy from thermal differences—in the case of the illustrated device, from the difference in temperature at interface 101 between hot surface 102 and cold surface 103. There are various means known in the art for configuring a thermoelectric generator 100. The thermoelectric generator 100 powers a circuit 104, having polarities as shown.

The terms “cold” and “hot” are used relatively herein, not absolutely. Fluid is labeled “cold” if it tends to be cooler than fluid that is labeled “hot”. Fluid is labeled “hot” if it tends to be warmer than fluid that is labeled “cold”.

FIG. 1b is a schematic diagram of a photovoltaic cell module 150. The module includes one or more photovoltaic cells 151. A photovoltaic cell 151 receives incoming solar radiation 152, and converts a fraction of the solar energy into electricity flowing through a circuit 154. A variety of types of photovoltaic cells 151 are known in the community, with better and more efficient technologies being developed; likewise, for technologies to combine photovoltaic cells 151 into a photovoltaic cell module 150.

### BRIEF DESCRIPTION OF THE DRAWINGS

FIG. 1a is a schematic diagram of a thermoelectric generator.

FIG. 1b is a schematic diagram of a photoelectric cell module.

FIG. 2 is a top cutaway view of an exemplary reversible thermoelectric generator.

FIG. 2a is a rightward-facing cross section at A-A through FIG. 1.

FIG. 2b is a leftward-facing cross section at B-B through FIG. 1.

FIG. 3a is a cross section through a panel showing left to right flow and a photovoltaic cell module embedded in a solar-facing surface of the panel.

FIG. 3b is a cross section through a panel showing right to left flow and a photovoltaic cell module embedded in a solar-facing surface of the panel.

FIG. 3c illustrates an exemplary alternative positioning of a cold fluid tank.

### DETAILED DESCRIPTION OF EXEMPLARY EMBODIMENTS

This description provides embodiments of the invention intended as exemplary applications. The reader of ordinary skill in the art will realize that the invention has broader scope than the particular examples described here. It should be noted from the outset that the drawings, and the elements depicted by the drawings, may not be to scale.

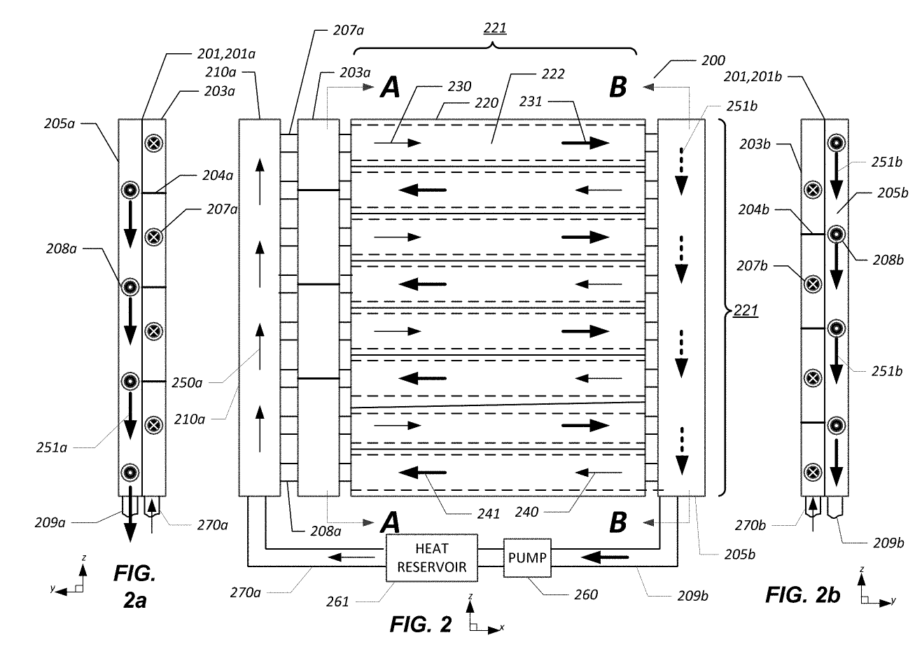

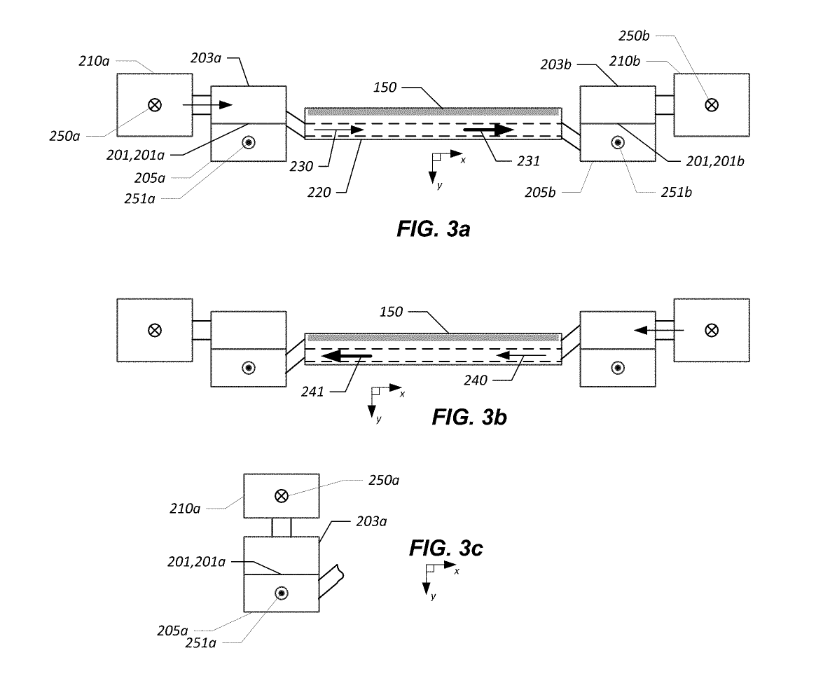

FIG. 2 is a top cutaway view of an exemplary solar thermoelectric generator (STG) 200. FIG. 2a is a rightward-facing cross section through FIG. 2 at A-A. FIG. 2b is a leftward-facing cross section through FIG. 2 at B-B. FIG. 3a and FIG. 3b show cross sections through a pair of adjacent solar panels 220, facing upward.

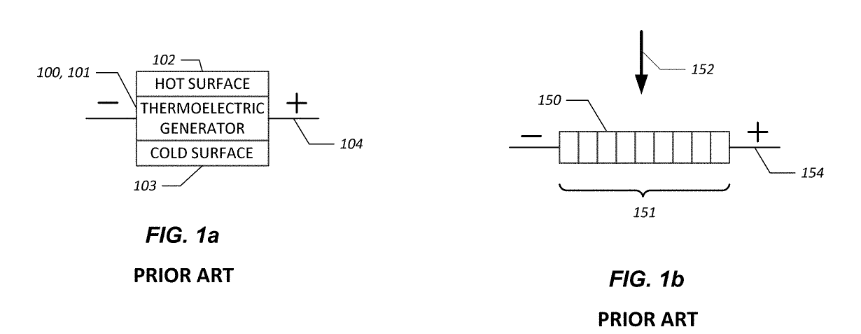

The STG 200 heats a liquid by exposure to sunlight. The liquid might be ethylene glycol, water, or some other liquid. Some of the heat is then removed from the liquid into a heat reservoir 261, resulting in cold (i.e., cooler) liquid. The cold liquid and the hot liquid are placed into thermal contact with each other at a thermoelectric interface 201, such as interface interface 201a or interface 201b, where electricity is generated. Although in FIGS. 2a and 2b the thermoelectric interface 201 is depicted for convenience as a line, in reality some thickness as in FIG. 1a can be expected. As mentioned previously, various approaches to implementing such an interface, functioning as a thermoelectric generator 100, are well known in the art. Any reasonable approach is in within the scope of the inventive concept.

The generated electricity may be stored in any technology for storing electricity, such as batteries, or the current may be used, wholly or in part, as it is generated to drive a circuit. The STG 200 may also store heat, in a heat reservoir 261, or simply remove it in a heat sink (not shown).

The STG 200 embodiment illustrated in FIG. 2 is a set of solar panels 220 arranged into a blind 221 for a window. In FIG. 2 we are looking through a window pane (not shown) of a building from outside. The portions of the device other than the panel may be hidden within window mullions (not shown). As shown, the panels 220 of the blind 221 are in the closed position, but preferably they can also be opened.

Note that other configurations of the panels 220 are possible within the scope of the invention. For example, the panels 220 might be installed on a rooftop. In such a configuration, the frame holding them might be horizontal, or at some acute angle with the horizontal.

Other than FIG. 1a and FIG. 1b, each figure near its figure number label shows coordinate axes that define its orientation. The directions shown correspond to an exemplary window installation of the thermoelectric generator 100. The x-axis is to the right, parallel to a face, or outer wall, of the building. The z-axis is upward, parallel to the face. The y-axis is inward, perpendicular to the face.

The panels 220 themselves are similar to those described in U.S. Pat. No. 8,650,877 (the '877 patent), entitled “Solar Panels that Generate Electricity and Extract Heat: System and Process”, which issued on Feb. 18, 2014, and is hereby incorporated by reference in its entirety. This patent describes illustrative mechanisms for rotating panels 220 in a blind 221, such as the panels 220 described herein, to keep them solar-facing.

The panels 220 are also similar to those described in application number PCT/US14/10650 (the '650 application), filed Jan. 8, 2014, which is hereby incorporated by reference in its entirety. The inventions described in the '877 patent and the '650 application use thermal expansion to drive electrical generators. Indeed, any of the panel configurations described in those documents, and the means for opening and closing them (e.g., FIGS. 3a-3d of the '877 patent), could be used in some embodiments of the present invention. In contrast, however, the present invention produces electricity by thermoelectric processes rather than by thermal expansion and turbines.

As will be described below, there are many applications of the present invention in addition to solar panels. However, solar panel embodiments illustrate many of the concepts, and so will be our main focus in this description.

It should be noted at this point that the figures contain many symmetries and many repeated features. When redundant labeling would obscure rather than enhance readability of the figures, some reference numerals have been omitted. We will follow the convention that reference numbers on the left side of the blind are labeled with a numeral followed by ‘a’; their counterparts to the right, ‘b’. To indicate some feature that is in common to left- and right-side components, we will drop the ‘a’ and ‘b’. For example, the embodiment shown has a left interface interface 201a, and a right interface interface 201b, each of which is a thermoelectric interface 201. Generally, for clarity we will omit a generic/common label in the drawings when corresponding left and right components are explicitly labeled.

A set of solar panels 220 may be assembled into a blind 221. The illustrative blind 221 in FIG. 2 has eight laterally-oriented panels 220, arranged vertically. Typically, the panels 220 will be sandwiched between at least two transparent or translucent window panes, such as glass panes (not shown), parallel to a face of a building. The blind 221 may have a frame that can be retrofit on an existing window. Some or all of the functional components of the blind 221, other than the panels 220 themselves, but including some or all of the frame, may be enclosed within mullions between windows.

The lateral and vertical extents of the panels 220 of the blind 221 are labeled in the figure with braces. The STG 200 includes a fluid transport system, which may be any combination of pipes, flexible tubing, connectors, channels, and valves. We will refer to this fluid transport system as a conduit or tubing system in this document, without loss of generality. In particular, “tubing” does not necessarily imply flexible tubing. Fluid in a cavity or channel within the body of a panel 220 is heated through the outer window pane by incoming solar radiation. Fluid flow may be forced by one or more pumps 260, or by thermal expansion of fluid due to heating as described in '877 patent.

Conservation of mass and the conduit system govern the flow direction at any point, designated by arrows in the figures. Thin arrows, typified by arrow 230, arrow 240, and arrow 250a, indicate “cold” fluid. Thicker and darker arrows, typified by arrow 231, arrow 241, and arrow 251b, indicate “hot” fluid.

In the embodiment shown, each panel 220 of the blind 221 has an internal channel 222 or tube. The panels 220 and the channels 222 may be produced, for example, by extrusion of a metal such as aluminum, or a metal alloy. In other embodiments, a panel 220 might enclose a pipe or tube. Preferably but not necessarily, all panels 220 in a single window will be similarly configured. Some channel embodiments are illustrated in the '877 patent. In the embodiment shown, adjacent panels 220 have flow in opposite directions, as indicated by arrows in FIGS. 2, 3a, and 3b. In other embodiments, flow through adjacent panels 220 may be in the same direction. As cold fluid moves through a panel 220, it is heated by incoming solar radiation (insolation) from outside (i.e., from the -y direction) and becomes hot fluid. In the illustrated embodiment, fluid moving through panels 220 to the right (-x-direction) is part of a clockwise circulation loop; to the left (-x-direction), a counterclockwise loop. Each of these loops may have a separate pump and a separate heat reservoir/sink, although only pump 260 and heat reservoir 261 of the clockwise loop are shown in the figures.

Cold fluid enters a panel 220 from a cold manifold 203, such as cold manifold 203a or cold manifold 203b. The cold manifold 203 is in thermal contact with a hot tank 205, such as hot tank 205a or hot tank 205b, through which hot fluid that has exited from (in this embodiment) half of the panels 220 flows. Partitioning into cold manifolds 203 prevents flow of cold fluid in the z-direction, preventing the cold fluid from warming up much except within the panels 220. This approach maintains the temperature difference across the thermoelectric generating interface 101 between cold manifold 203 and hot tank 205.

As shown by FIGS. 3a and 3b, in the illustrated embodiment both left and right sides of the panels are configured with cold manifolds 203 positioned outward in y (i.e., toward the exterior of the building or source of light) from hot tanks 205. FIG. 2 omits, or cuts out, the overlying right-hand cold manifold 203 and associated cold tank 210 so that a complete clockwise loop of fluid through the STG 200 can be visualized. FIG. 3a also shows a portion of a clockwise loop. Portions of the counterclockwise loop are shown in FIG. 3b shows a portion of a counterclockwise loop, as do portions of FIGS. 2, 2a, 2b, 3a, and 3b.

In FIG. 2, hot fluid of the clockwise loop exiting the panels 220 flows through hot tank 205b and tube 209b. It is propelled forward by pump 260 into heat reservoir 261. The pump 260 could be positioned at various other locations in the loop and, in some embodiments, there might be two or more pumps. A heat reservoir 261 is a sink for heat that may also store the heat for other use. For example, the heat might be used to heat the building during cold weather. The heat might be used to run the STG 200 in reverse, using the temperature contrast between lower temperatures caused by nighttime cooling and stored relatively hot liquid. Both loops might be configured to work off a single heat sink, or there might be a second one (or even several of them). After removal of heat in heat reservoir 261, the cold fluid flows through tube 207a, and into cold tank 210a. To prevent the cold fluid from prematurely gaining heat, cold tank 210a may be insulated from cold manifold 203a, where it encounters interface 201a. To maintain the temperature contrast with the hot fluid, baffles or partitions typified by partition 204a separate adjacent cold manifolds 203, so that cold fluid flow is constrained to be dominantly in the x-direction. The cold fluid passes from cold tank 210a through tube 207a into cold manifold 203a. In this embodiment, hot fluid moves downward (-z-direction), and interacts with the cold fluid through interface 201a. This is most easily seen in FIGS. 2a and 3a. From the cold manifolds 203, the cold fluid moves into panels 220, where it is heated. The hot fluid then moves downward in hot tank 205b, as indicated by arrow 251b. These arrows in hot tank 205b are shown dashed, to indicate that they would actually be located below the cold manifold 203b. The counterclockwise loop in this embodiment is a mirror image of the clockwise loop. FIG. 3c illustrates an alternative position for a cold tank 210a relative to the cold manifolds 203.

So far in this document, we have described a set of solar panels 220, formed into a blind 221, that use thermal contrasts to generate electricity, and a cooling system to enhance the thermal contrast and to remove heat from the panels 220—heat that can be applied to other uses. FIGS. 3a and 3b illustrate a photovoltaic cell module 150, embedded in panels 220 of a blind 221, as either an alternative or a supplemental mechanism for generating electricity in panels 220 cooled by fluid flow. Any of the many forms of photovoltaic cells 151, and/or configuration of such cells into modules, might be used for this purpose. The modules in the respective panels will be connected to an electrical circuit (not shown). Electricity produced by the modules can be used directly in a building system or the electrical grid, or stored in batteries or any of the other systems available for storing electricity.

Many types of photovoltaic cells 151 lose effectiveness in generating electricity when they get hot. A panel cooling system such as the one already described can be used to remove heat from the embedded photovoltaic cell modules 150. Thus, the cooling system can serve the dual purposes of maintaining a thermal contrast for thermoelectric generation and improving effectiveness of the photovoltaic cell modules 150.

Effectiveness of photovoltaic cells 151 is also known to be degraded by infrared (IR) radiation. Many modern buildings use a window coating to filter out incoming IR radiation. In embodiments in which the panels 220 are behind a window pane, such a filtering layer is preferable.

Note, however, that photovoltaic cell electricity generation might also be used without thermoelectric generation. In such embodiments, the cooling system might be simplified, since maintaining a temperature contrast across an interface would no longer be essential. But the cooling system, in such embodiments, would nevertheless to cool the photovoltaic cells 151, improving their effectiveness. This implies that (1) flow might not alternate between adjacent panels; and (2) manifolds to maintain temperature contrast might not be used.

The inventive concept is not limited to panels 220 in a blind 221. The same system configuration might be adapted, for example, to a parking lot or within the roof of a building. As mentioned previously, a STG 200 can also be run in reverse, using external cooling and stored hot fluid. Note too that adjacent windows could share components, such as hot tanks 205, cold manifolds 203, and cold tanks 210.

Of course, many variations of the above method are possible within the scope of the invention. The present invention is, therefore, not limited to all the above details, as modifications and variations may be made without departing from the intent or scope of the invention. Consequently, the invention should be limited only by the following claims and equivalent constructions.

1. An apparatus, comprising:
a) a set including a plurality of panels, each panel in the set containing a channel extending latitudinally through the panel, the channel adapted to being heated by solar insolation incident upon a panel surface;
b) a heat sink, through which relatively hot fluid exiting a subset of the set of panels flows, the subset including a plurality of the panels, which removes heat from the relatively hot fluid, so that fluid exiting the heat reservoir is relatively cool fluid;
c) a thermoelectric interface, whereby electricity is produced from temperature contrast, having a first side that is in thermal contact with the relatively hot fluid and a second side that is in thermal contact with the relatively cool fluid; and
d) an electrical circuit that uses electricity generated by the thermoelectric generator;
e) a first closed fluid conduit loop, that includes a fluid propulsion mechanism and the channels in a first subset of the panels;
f) a plurality of manifolds, each manifold configured to
(i) receive relatively cool fluid that has been cooled by the heat sink,
(ii) place relatively cool fluid into thermal contact with a thermoelectric interface within the manifold,
(iii) isolate fluid in each of the manifolds from fluid in adjacent manifolds, and
(iv) transfer relatively cool fluid into the respective channel in each of the first subset of panels.

2. (canceled)

3. (canceled)

4. (canceled)

5. (canceled)

6. The apparatus of claim 1, further comprising:
g) a mullion that encloses the plurality of manifolds and the thermoelectric interface.

7. The apparatus of claim 1, further comprising:
g) a tank configured to deliver relatively cool fluid from the heat sink to the plurality of manifolds, wherein the tank is thermally insulated from the manifolds.

8. (canceled)

9. An apparatus, comprising:
a) a set including a plurality of panels, each panel in the set containing a channel extending latitudinally through the panel, the channel adapted to being heated by solar insolation incident upon a panel surface;
b) a heat sink, through which relatively hot fluid exiting a subset of the set of panels flows, the subset including a plurality of the panels, which removes heat from the relatively hot fluid, so that fluid exiting the heat reservoir is relatively cool fluid;
c) a thermoelectric interface, whereby electricity is produced from temperature contrast, having a first side that is in thermal contact with the relatively hot fluid and a second side that is in thermal contact with the relatively cool fluid; and
d) an electrical circuit that uses electricity generated by the thermoelectric generator;
e) a first closed fluid conduit loop, that includes a fluid propulsion mechanism and the channels in a first subset of the panels;
f) a second closed fluid conduit loop, which includes a fluid propulsion mechanism and channels in a second subset of the panels that is distinct from the first subset, wherein the first closed fluid conduit loop and the second closed fluid conduit loop circulate fluid in mutually opposite directions.

10. (canceled)

11. (canceled)

12. (canceled)

13. A method, comprising:
a) forcing fluid through a first plurality of panels in a first closed-loop system with a pump, each panel containing a channel extending latitudinally through the panel;
b) receiving solar insolation incident upon a respective surface of each of the panels, thereby adding heat to fluid in the channels;
c) circulating fluid that has been heated in the channels into thermal contact with a first side of an interface of a thermoelectric generator; and
d) after the circulating step,
(i) using a heat sink to cool fluid that was in thermal contact with the first side of the interface, and
(ii) circulating that cooled fluid into thermal contact with a second side of the interface, thereby generating electricity.

14. The method of claim 13, wherein the plurality of panels are positioned between two panes of a window.

15. The method of claim 14, further comprising:
e) using an automated system, mechanically rotating each of the panels synchronously about a respective longitudinal axis.

16. The method of claim 14, wherein the interface is enclosed in a mullion of the window that is adjacent to the panes.

17. The method of claim 13, further comprising:
e) forcing fluid through a second plurality of panels in a second closed-loop system with a pump, each panel in the second plurality containing a channel extending latitudinally through the panel, wherein the second closed-loop system has an opposite circulation direction from the first closed-loop system.

18. The method of claim 17, wherein a panel in the first plurality of panels is adjacent to two panels in the second plurality of panels.

19. (canceled)

20. (canceled)
